(19) United States
(12) Patent Application Publication
(10) Pub. No.: US 2007/0246839 A1
(43) Pub. Date: Oct. 25, 2007

(54) Method of proximity pin manufacture

(75) Inventors: Harald Herchen, Los Altos, CA (US); Sharathchandra Somayaji, Sunnyvale, CA (US); Brian C. Lue, Mountain View, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Applied Materials, Inc., Santa Clara, CA (US)

(21) Appl. No.: 11/408,465

(22) Filed: Apr. 21, 2006

(51) Int. Cl. H01L 23/52

(52) U.S. Cl. 257/784

(57) ABSTRACT

A method and apparatus related to a substrate support structure are provided. In accordance with one embodiment of the present invention, a method for manufacturing a substrate support structure including proximity pins and apparatus for supporting a substrate inside a semiconductor processing equipment are provided. The method includes providing a plate assembly comprising a plate and a plate surface and forming a plurality of recessed regions in the plate surface. Additionally, the method includes filling the recessed regions with a bonding material including epoxy material and placing a plurality of support members into the epoxy-coated recessed regions. The method further includes pushing the support members with a flat plate held up from the surface by shims to provide a uniform local height of the support members, followed by a curing step to fix the supporting members to the recessed regions.

### BACKGROUND OF THE INVENTION

The present invention relates to semiconductor processing equipment. More particularly, the present invention provides a method and apparatus for providing local height control for substrate support structures of semiconductor processing equipment. Merely by way of example, the invention has been applied to substrate support structures. However, it would be recognized that the invention has a much broader range of applicability as well.

Substrate support structures or chucks are widely used to support substrates within semiconductor processing systems. These chucks are used to retain semiconductor wafers or other work-pieces in a stationary position during processing. Two examples of particular types of chucks used in semiconductor processing systems include electrostatic chucks (e-chucks) and vacuum chucks.

One potential problem with such chucks is that if a substrate is loaded directly onto the upper surface of the chuck during substrate processing, the chuck surface can abrade the material present on the backside of the substrate, resulting in the introduction of particulate contaminants to the process environment. The particulate contaminants can adhere themselves to the backside of another substrate and be carried to other process environment or cause defects in the circuitry fabricated upon the substrate. As the semiconductor device geometry has become smaller with each generation of ICs, these particulate contaminants can cause a serious yield loss and degradation of device characteristics and reliability as well.

One method of reducing the number of particles generated on the backside of the substrate is to minimize the contact area of the substrate to the surface of the plate assembly. This can be accomplished by, for example, an array of proximity pins or support members that space the substrate off the surface of the plate assembly have been utilized. The particulate contaminants can be suppressed by installing a plurality of proximity pins or support members on the chuck surface which reduce the contact area between the chuck surface and backside of substrate.

Proximity pins can be installed by various methods. One known method, for example, is to form a plurality of recessed regions in the surface of the plate assembly and provide a plurality of support members having a diameter larger than the width of the recessed regions. Then the support members are pressed into the recessed regions to be placed into a position.

While this technique may be applicable for some applications, new and improved techniques for installing proximity pins and new and improved method and apparatus for supporting a substrate inside semiconductor processing equipment are desirable.

### BRIEF SUMMARY OF THE INVENTION

The present invention relates to semiconductor processing equipment. More particularly, the present invention provides a method and apparatus for providing local height control for substrate support structures of semiconductor processing equipment. Merely by way of example, the invention has been applied to substrate support structures. However, it would be recognized that the invention has a much broader range of applicability as well.

In a specific embodiment, the invention provides a method for manufacturing a substrate support structure including proximity pins formed on the plate assembly surface. The method includes providing a plate assembly including a plate and plate assembly surface and forming a plurality of recessed regions in the plate assembly surface. The recessed regions are filled with a bonding material and a plurality of support members are placed in the recessed regions. The method further includes pushing the support members with a flat plate held up from the surface by shims to provide a uniform local height control of the support members and curing the bonding material.

In another embodiment, the invention provides a substrate support structure including a plate assembly further including a plate and plate surface. The substrate support structure further includes a plurality of recessed regions formed on the surface and having a predetermined width and a plurality of support members bonded into the recessed regions by a bonding material, wherein the diameter of the support members is smaller than that of the width of the recessed regions.

Many benefits are achieved by way of embodiments of the present invention over conventional techniques. For example, the present technique provides a uniform local height control of the proximity pins while avoiding any potential damage to the surface of the chuck, which can be a soft polyimide layer formed on the chuck in some embodiments. The uniform local height control and reduced height of the proximity pins increase the thermal transfer rate from the plate assembly to the substrate, thereby decreasing the temperature ramp up time and increasing manufacturing throughput. Moreover, an increase in thermal coupling between the substrate and plate assembly results in improvements in the thermally dependent properties of layers formed on the substrate. These and other benefits will be described in more detail throughout the present specification and more particularly below.

Other objects, features and advantages of the present invention will become apparent from the following description of the embodiments of the invention taken in conjunction with the accompanying drawings.

### BRIEF DESCRIPTION OF THE DRAWINGS

The accompanying drawings, which are incorporated herein and form a part of the specification, illustrate the present invention and, together with the description, further serve to explain the principles of the invention and to enable a person skilled in the pertinent art to make and use the invention.

FIG. 1 is a simplified cross-sectional view of a substrate processing chamber including the substrate support structure;

FIG. 2 is a simplified plan view of one example of a vacuum chuck;

FIGS. 3A-3B are simplified cross-sectional views of proximity pins placed in recessed regions of a vacuum chuck or E-chuck according to an embodiment of the present invention;

FIGS. 4A-4D are simplified cross-sectional views of a method of fabricating a substrate support structure according to an embodiment of the present invention;

FIG. 5 is a process flow illustrating a method of fabricating a substrate support structure according to an embodiment of the present invention.

### DETAILED DESCRIPTION OF THE INVENTION

The present invention generally relates to semiconductor processing equipment. More particularly, the present invention provides a method and apparatus for providing local height control for substrate support structures of semiconductor processing equipment. Merely by way of example, the invention has been applied to substrate support structures. However, it would be recognized that the invention has a much broader range of applicability as well.

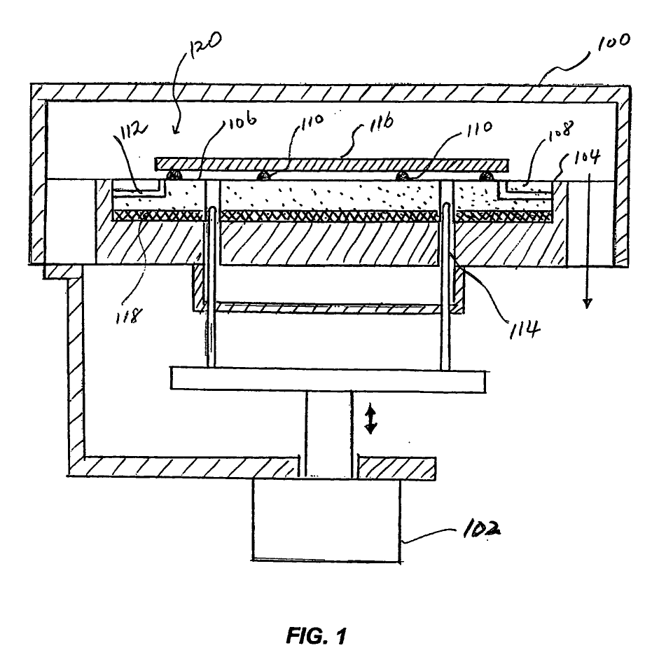

FIG. 1 is a simplified cross-sectional view of a substrate processing chamber 100. Accordingly to one embodiment of the invention, chamber 100 includes a substrate support structure 120 including a plurality of proximity pins 110 spaced across the surface of a plate assembly 104. Proximity pins 110 minimize the contact area between the substrate 116 and plate assembly surface 106 and maintain a substantially uniform distance between the substrate and surface 106.

As shown in FIG. 1, the substrate support structure 120 operates as a vacuum chuck and the plate assembly 104 includes a plate 108, a plate assembly surface 106, and a vacuum port 112. In this configuration a vacuum source (not shown) is used to create a negative pressure in the vacuum port 112, thus creating a reduced pressure behind the substrate 116, which causes the substrate 116 to be pulled down toward the surface of the proximity pins 110.

The plate 108 may be made from a thermally conductive material such as aluminum, copper, graphite, aluminum-nitride, boron nitride, silicon carbide, and/or other material, and is in communication with a heat exchanging device 1118. Additionally, the plate may be made from anodized materials, including anodized aluminum and sealed anodized aluminum. Although FIG. 1 illustrates a vacuum chuck, alternative embodiments of the present invention provide methods and apparatus for supporting a substrate using an electrostatic chuck as well.

The invention may be embodied in other specific forms without departing from the spirit or essential characteristics thereof. The present embodiment is therefore to be considered in all respects as illustrative and not restrictive, the scope of the invention being indicated by the appended rather than by the foregoing description and all changes which come within the meaning and range of equivalency of the claims are therefore intended to be embraced therein.

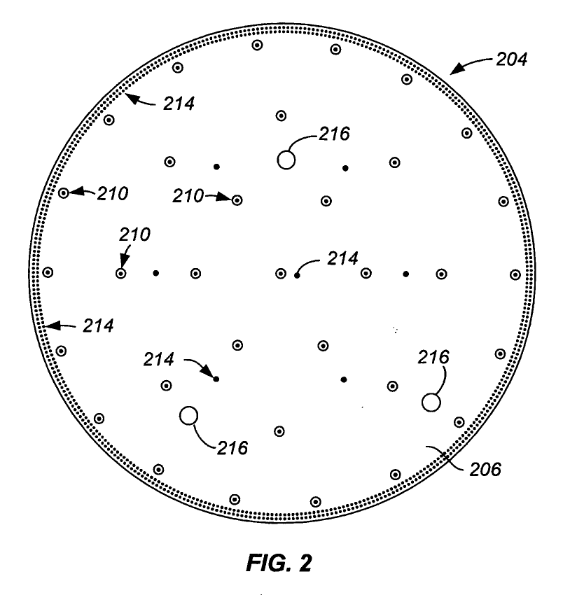

FIG. 2 is a simplified schematic plan view of one example of a vacuum chuck. Two examples of particular types of chucks used in semiconductor processing systems include vacuum chucks and electrostatic chucks (e-chucks). The surface of the plate assembly 104 and a plurality of proximity pins 110 are illustrated in FIG. 2 with no substrate 116 on top of the proximity pins 110. Thus, this FIG. 2 illustrates one possible configuration of proximity pins 110 and vacuum ports 112. FIGS. 1 and 2 also illustrate a configuration having a lift assembly 102, lift pin hole 216, and lift pin 114 extending through the plate assembly surface 106 to lift the substrate 116 off the plate assembly surface.

In general a number of proximity pins 110 are spaced across the surface of the plate assembly 104 so that the contact area can be minimized and the gap between the substrate and the plate assembly surface 106 can be maintained at a substantially uniform distance. Additionally, other embodiments of the present invention utilize an electrostatic chucking device or other conventional methods of forcing the substrate against the plate assembly. A soft material such as polyimide or Kapton™ can be formed on the surface of the plate assembly for non-vacuum chuck purpose.

If a substrate is loaded on the plate assembly in direct contact with a chuck surface during substrate processing, the contact area between the substrate and the surface of the plate assembly 104 will increase the thermal coupling and reduce the time it takes a substrate to reach the desired process temperature. However, increasing the contact area is often undesirable as explained above because the plate surface can abrade the material present on the backside of the substrate, resulting in the introduction of particulate contaminants to the process environment.

Accordingly, embodiments of the invention include an array of proximity pins or support members that space the substrate off the surface of the plate assembly. While the use of proximity pins reduces the number of particles generated, they may tend to reduce the thermal coupling between the substrate and the plate assembly. Therefore, it is often desirable to minimize the height of the proximity pins above the surface of the plate assembly to improve the thermal coupling, while also assuring that the substrate will not touch the surface of the plate assembly.

Proximity pins can be installed by various methods. In some applications, for example, sapphire spheres are pressed into machined holes in the plate assembly surface to act as proximity pins. However, it is often difficult to mechanically control the height to which the spheres extend above the surface of the plate assembly. Due to their height uncertainty and for other reasons like substrate warpage, the height of the support members made by this method is usually set in a range from 100 to 150 microns. This value is high enough to reduce the thermal uniformity of the heat transfer between the substrate and the plate assembly, causing a slow temperature ramp up rate or at least a temperature non-uniformity within a substrate. Moreover, a soft material such as polyimide or Kapton™, formed on the surface of the plate assembly used for E-chucking purposes can be damaged during the installation of the sapphire spheres.

In a specific embodiment of the present invention, the thermal coupling is increased by decreasing the distance between the substrate and the chuck. Increased thermal coupling between the substrate and the plate assembly allows for reduction in the processing time, increased system throughput, and increased control over critical dimensions (CD). As evident to one of skill in the art, decreasing the spacing between the substrate and the chuck will lead to an increase in convective heat transfer across the gap.

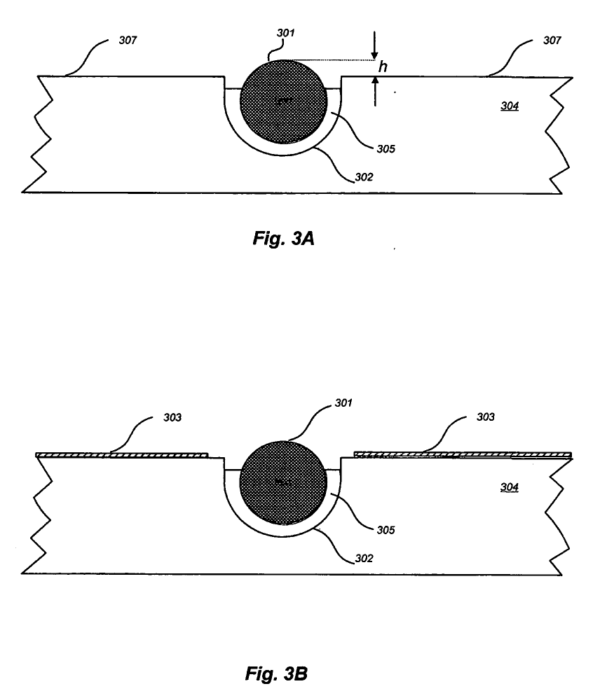

FIGS. 3A-3B illustrate a simplified cross-sectional views of the proximity pins placed in recessed regions of a vacuum chuck or E-chuck according to an embodiment of the present invention. Referring to FIG. 3A, a cross-sectional view of a proximity pin 301 placed in the recessed region 302 of the vacuum chuck is illustrated. Additional proximity pins and other parts of the substrate support are omitted for purposes of clarity. According to one embodiment of the present invention, a portion of a substrate support structure includes a plate 304 and proximity pin 301 made of sapphire sphere placed in the recessed region 302. As illustrated, proximity pin 301 extends to a predetermined height “h” above the substrate receiving surface 307. The substrate can be loaded on the proximity pin 301 and can be biased towards the plate 304 by use of a vacuum chucking device.

Referring to FIG. 3B, a cross-sectional view of the proximity pins 301 placed in the recessed region 302 of the E-chuck is illustrated. Another embodiment of the present invention provides an accurately controlled small contact area proximity pin 301 that is placed in the recessed region 302 partially filled with a bonding material 305. The substrate can be loaded on the proximity pin 301 and can be biased towards the plate 304 by use of an electrostatic chucking device. In FIG. 3B, a thin layer of polyimide or Kapton™ 303 is used for E-chucking purpose. One of ordinary skill in the art would recognize many variations, modifications, and alternatives.

Embodiments of the invention include an array of accurately controlled small height proximity pins 301 formed by the method as described more fully below. As illustrated in FIGS. 3A-3B, proximity pins 301 are placed in recessed regions formed in the plate assembly including the plate 304. Preferably, the proximity pins are fabricated from a material with a low coefficient of friction so that contact between the proximity pins and the substrate may produce a reduced number of particles.

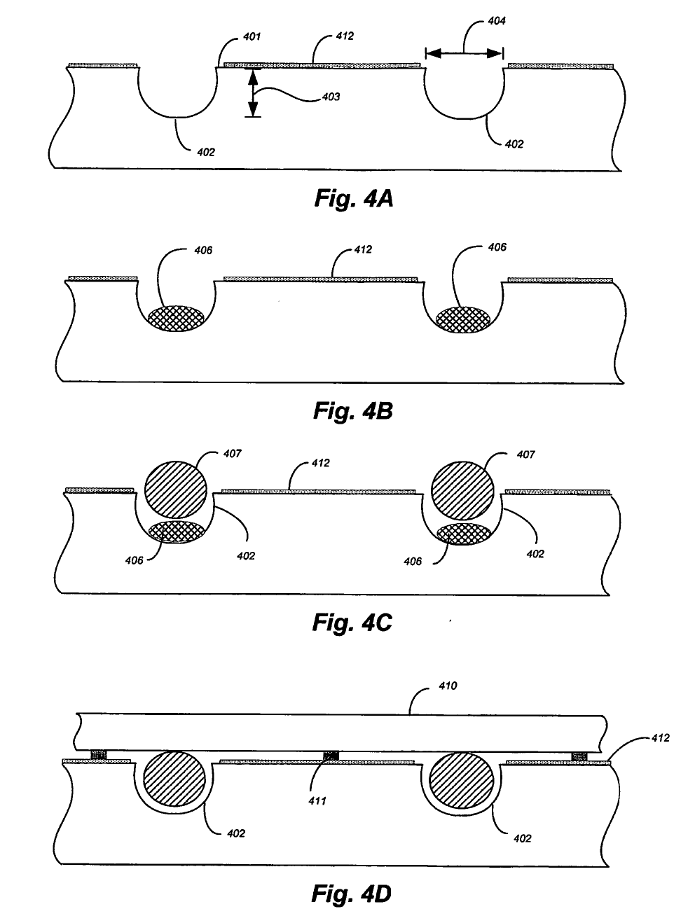

FIGS. 4A-4D are simplified cross-sectional views of a method of fabricating a substrate support structure according to an embodiment of the present invention. As illustrated in FIG. 4A, a plate assembly including a plate 400 is provided. Generally, the plate is adapted to support a substrate, for example a silicon wafer, during semiconductor processing operations. For purposes of clarity, various components of the plate assembly including vacuum and electrodes for electrostatic chucking mechanisms, heat exchanger elements, lift pin holes, etc. are omitted from the figures. One of ordinary skill in the art will appreciate that the plate is one portion of a larger plate assembly as illustrated in FIG. 1.

The plate 400 is an aluminum plate coated with a polymer. The plate may be an aluminum plate coated with Teflon® manufactured by Dupont Incorporated of Wilmington, Del. or Tufram® manufactured by General Magnaplate Corporation of Linden, N.J. In another embodiment, the plate 400 can be fabricated from stainless steel, silicon carbide, copper, graphite, aluminum, aluminum nitride, aluminum oxide, boron nitride, or combinations/laminates of these materials.

FIG. 4A shows a cross-sectional view of recessed regions 402 formed in an upper substrate receiving surface 401. Polyimide layer 412 can be optionally placed on the surface 401 of the plate 400 as shown in FIGS. 4A-4D. The recessed regions 402 are formed using methods well known to one of skill in the art, for example, etching, ion milling, electric discharge machining, or laser ablation. In a specific embodiment, the recessed regions are formed with a predetermined depth 403 and width 404. In the embodiment of the present invention, the recessed regions are generally cylindrical in shape, although this is not required by the present invention. Recessed regions of other shapes, for example, square, are utilized in alternative embodiments. The width and the depth of the recessed regions may range from about 0.2 mm to about 5 mm subject to the dimension and target height of the proximity pins.

After forming the recessed regions 402 in FIG. 4A, a bonding material 406 such as epoxy material is applied into the recessed regions 402, as illustrated in FIG. 4B. In one embodiment, bonding material 406 is a thermosetting epoxide polymer that is cured (polymerizes and crosslinks) thermally or when mixed with a catalyzing agent or hardener. An epoxy such as MasterBond EP46HT™ bonds well to dissimilar materials and has low outgassing properties and high resistance to chemicals. In addition, this type of epoxy has durability against low and high temperature. Because of these outstanding properties as adhesive and the ease with which it can be poured or cast without forming bubbles, epoxy is especially useful as a bonding material for fixing proximity pins.

Referring to FIG. 4C, proximity pins or support members 407 are placed into the epoxy-filled recessed regions 402. As illustrated in FIG. 4C, the support members 407 are spherical in shape and have a diameter smaller than the width of the recessed regions. In one embodiment of the present invention, the support members 407 are sapphire precision spheres of predetermined diameter, for example, a diameter of 1.5 mm.

As illustrated in FIG. 4D, the support members 407 are pressed into the recessed regions 402 by a flat plate 410 so that an upper surface of the support members 407 lies in the plane defined by the lower surface of the flat plate 410. Here, since the diameter of the support members 407 is designed to be smaller than the width of the recessed regions, the height of the support member 407 can be uniformly controlled by gently pushing these members with the flat plate as illustrated in FIG. 4D.

Specifically, support members 407 can be placed into a position of the recessed regions by applying downward pressure from the flat plate 410 placed on the support members 407. The flat plate 410 has an optically flat lower surface and a plurality of shims 411 are positioned between the flat plate 410 and polyimide layer 412. The shims can be made of stainless steel and Kapton™ film since the former is readily available and the latter is easy to cur and has a tight thickness tolerance. It is also possible to machine a recess into the central region of a single plate to form a shim in the outer part of that plate, and then the outer part of that plate would effectively be the shim since it keeps the inner part where the support members are from descending too far. Shims can be put on the plate surface by hand or could be machined into a plate by removing material elsewhere as described above, in which case the shims become physically part of the flat disk.

The pushing step is completed when the shims 411 are in firm contact with both the optically flat lower surface of the plate 410 and upper surface of the polyimide layer 411 (or surface 401 in case polyimide layer 411 is not in use).

The height of the support members made by this method is set in a range from 20 μm to 100 μm for optimum heat transfer between the plate assembly and substrate. Accordingly, a preferred height of shims 411 is between 20 μm to 100 μm if polyimide layer 412 is not used. This height can be further lowered by 10 μm to 20 μm in case polyimide layer 412 is used. In one embodiment of the present invention, a preferred height of shim 411 is about 70 μm. As illustrated, proximity pin 407 extends to a predetermined height above the surface 412 substantially equal to the height of the shims 411.

After supporting members 407 are placed in the correct position within the recessed regions, the epoxy layer is cured to permanently fix the supporting members 407 to the recessed regions.

According to another embodiment of the present invention, small ceramic particles or beads having a diameter in a range from 10 μm to 50 μm are added to the bonding material by mixing the beads with the uncured epoxy material. The mixture is then placed in the recessed region and support members 407 are placed on it. The assembly is then thermally cured. A suspension of small ceramic particles added to the epoxy layer increases the viscosity of the bonding material. The minimum viscosity is about 10,000 cps (centimeter per second) and a preferred viscosity is around 20,000 cps. Although higher viscosity is better from a support point of view, it becomes hard to dispense as viscosity increases. A maximum viscosity level is around 200,000 cps. This increase of viscosity allows the force of gravity to be compensated during that curing, providing another method of keeping the ball in place.

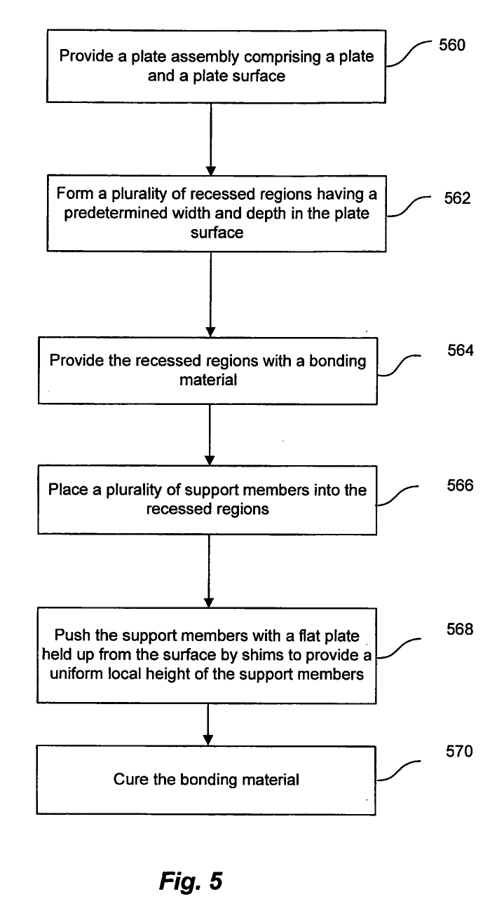

FIG. 5 is a process flow illustrating a method of fabricating a substrate support structure according to an embodiment of the present invention. In step 560, a plate assembly comprising a plate and plate surface is provided. In step 562, a plurality of recessed regions having a predetermined width and depth are formed in the plate surface. In the next step 564, a bonding material is poured into the recessed regions. In the present embodiment, epoxy is used as the bonding material. Then, a plurality of supporting members made of sapphire balls having a diameter of about 1.5 mm are placed into the epoxy-filled recessed regions at step 566.

Generally, a suitable ball material is hard enough to withstand the biasing force without appreciable deformation and is not easily abraded by the interaction with backside of the substrate. The material of the supporting members or proximity pins may be sapphire, diamond, diamond-like carbon, boron nitride, silicon dioxide (SiO₂), silicon (Si), a metal (e.g., nickel, titanium, titanium nitride, molybdenum, tungsten), a ceramic material, a polymeric material (e.g., polyimide or Teflon®) or other suitable material. One of ordinary skill in the art would recognize many variations, modifications, and alternatives.

In step 568, support members are gently pushed by a flat plate held up from the surface by accurate shims to provide a uniform local height of the support members. Proximity pins having a predetermined height are fixedly placed into the recessed regions by curing the bonding material in step 570.

As illustrated in FIGS. 4A-4D and FIG. 5, the height control of the proximity pins is provided with such a low force that a soft material such as polyimide or Kapton™ stack 412, generally used for E-chucking purpose, is not damaged during the installation of the proximity pins in the present invention.

According to the above-described embodiments, a reliable and uniform local height control of the proximity pins can be achieved. While various embodiments of the present invention have been described above, it should be understood that they have been presented by way of example only, and not limitation. It will be apparent to persons skilled in the relevant art that various changes in form and detail can be made therein without departing from the spirit and scope of the invention. Thus, the breadth and scope of the present invention should not be limited by any of the above-described exemplary embodiments, but should be defined only in accordance with the following claims and their equivalents.

What is claimed is:

1. A method of manufacturing a substrate support having a substrate receiving surface, the method comprising:
forming a plurality of recessed regions having a predetermined width and depth in the substrate receiving surface;
for each of the plurality of recessed regions, at least partially filling the recessed region with bonding material and placing a support member within the recessed region and over the bonding material;
positioning a plurality of shims having a predetermined height over the substrate receiving surface and positioning a plate having a substantially flat lower surface over the substrate receiving surface such that the lower surface of the plate faces the substrate receiving surface and plurality of shims are between the plate and the substrate receiving surface;
pressing the plate towards the substrate support until the plurality of shims are in firm contact with the substrate receiving surface and the lower surface of the plate to position the support members within the recessed regions such that each support member extends a predetermined height above the substrate receiving surface substantially equal to the height of the shims; and
curing the bonding material.

2. The method of claim 1 wherein the support members are spherical in shape and have a diameter smaller than the width of the recessed regions.

3. The method of claim 1 wherein the plurality of support members are made from a material selected from the group consisting of sapphire, diamond, diamond-like carbon, boron nitride, silicon dioxide, silicon, and a ceramic material.

4. The method of claim 1 wherein the plurality of shims are attached to the substrate receiving surface.

5. The method of claim 1 wherein the pressing step positions the support members less than 100 μm above the substrate receiving surface.

6. The method of claim 1 wherein the bonding material comprises epoxy material.

7. The method of claim 1 further comprising: adding a plurality of ceramic particles to the bonding material and mixing the ceramic particles with uncured bonding material before the mixture is placed in the recessed regions.

8. The method of claim 7 wherein the diameter of the ceramic particles is in a range from 10 μm to 50 μm.

9. The method of claim 1 wherein the pushing step pushes the support members with an optically flat surface of the plate.

10. The method of claim 1 wherein the substrate receiving surface is made from a material selected from the group consisting of aluminum, copper, graphite, aluminum-nitride, boron nitride, silicon carbide, anodized aluminum, and sealed anodized aluminum.

11. The method of claim 1 wherein the substrate receiving surface is coated with a layer of polyimide wherein the height control for the supporting members is provided with such a low force that the polyimide layer is not damaged during the installation of the supporting members.

12. A method of manufacturing a substrate support structure, the method comprising:
providing a plate assembly including a plate and plate surface;
forming a plurality of recessed regions having a predetermined width and depth in the surface;
partially filling the recessed regions with a bonding material;
placing a plurality of support members into the recessed regions;
pushing the support members with a flat disk held up from the surface by shims having a predetermined height to provide a uniform local height of the support members; and
curing the bonding material.

13. The method of claim 13 wherein the height of shim is in a range from 20 μm to 70 μm.

14. The method of claim 13 further comprising: adding a plurality of ceramic particles to the bonding material and mixing the ceramic particles with uncured bonding material to increase viscosity of the bonding material before the mixture is placed in the recessed regions.

15. The method of claim 14 wherein the size of the ceramic particles is in a range from 10 μm to 50 μm.

16. The method of claim 14 wherein the shims are physically part of the flat disk keeping the supporting members from descending when the flat disk is in firm contact with the plate surface.

17. A substrate support structure, the structure comprising:
a plate assembly including a support plate and plate surface;
a plurality of recessed regions having a predetermined width and depth formed on the surface of the support plate; and
a plurality of support members having a diameter smaller than the predetermined width of the recessed regions secured within the recessed regions by a bonding material such that each of the plurality of support members extends above the support plate surface by a predetermined height.

18. The substrate support structure of claim 17 wherein the support members are spherical in shape.

19. The substrate support structure of claim 17 wherein the plurality of support members are made from a material selected from the group consisting of sapphire, diamond, diamond-like carbon, boron nitride, silicon dioxide, silicon, and a ceramic material.

20. The substrate support structure of claim 19 wherein the diameter of the support members is approximately 1.5 mm.

21. The substrate support structure of claim 17 wherein the predetermined height is less than 100 μm.

22. The substrate support structure of claim 17 wherein the bonding material comprises epoxy material.

23. The substrate support structure of claim 22 wherein the bonding material further comprises a plurality of small ceramic particles having a diameter in a range from 10 μm to 50 μm.

24. The substrate support structure of claim 17 wherein the support plate is made from a material selected from the group consisting of aluminum, copper, graphite, aluminum-nitride, boron nitride, silicon carbide, anodized aluminum, and sealed anodized aluminum.
